(19) United States
(12) Patent Application Publication
(10) Pub. No.: US 2026/0178090 A1
(43) Pub. Date: Jun. 25, 2026

(54) CONFIGURABLE AIR DUCT FOR A COMPUTER CHASSIS

(71) Applicant: Quanta Computer Inc., Taoyuan City (TW)

(72) Inventors: Yaw-Tzorng TSORNG, Taoyuan City (TW); Jen-Jia LIOU, Taoyuan City (TW); Chia-Lin TSAI, Taoyuan City (TW); Fu-Jun YU, Taoyuan City (TW)

(21) Appl. No.: 19/000,821

(22) Filed: Dec. 24, 2024

(51) Int. Cl. G06F 1/20; H05K 7/20

(52) U.S. Cl. CPC G06F 1/20; H05K 7/20009

(57) ABSTRACT

A configurable duct for a computer chassis includes a fixed part and a movable part. The fixed part includes a first base wall, a first side wall, and a second side wall. The first base wall, the first side wall, and the second side wall form a portion of three sides of the configurable duct. The first base wall is configured to attach to the computer chassis. The movable part includes a second base wall, and is rotatably attached to the fixed part. The movable part is rotatable between a first configuration and a second configuration. In the first configuration, the second base wall is generally parallel to the first base wall and blocks access to a portion of the computer chassis. In the second configuration, the movable part is rotated away from the portion of the computer chassis such that the portion of the computer chassis is exposed.

### FIELD OF THE INVENTION

The present invention relates generally to an air duct for a computer chassis. More specifically, the present invention relates to an air duct having first and second configurations in which a movable part of the air duct alternatively blocks access to and exposes a portion of the computer chassis.

### BACKGROUND OF THE INVENTION

Space limitations of a modern computer chassis often result in a layered structure that has multiple distinct layers or trays of components that are tightly stacked together. Within any of the trays, the lack of overall space can require that components such as memory modules, printed circuit boards, riser boards, etc., are further installed in a layered fashion. This layering of the components necessarily results in some of the components being covered by other components. In such a situation, the replacement of a covered component requires removal of the covering components. Such removal of the covering components requires additional time and effort, and can be made more difficult by the inherent lack of space.

Due to cooling requirements, heat-generating components installed within the tight spaces of a modern computer chassis can provide a further challenge. Cooling air must have a path to flow into the computer chassis, over the heat-generating components, and back out of the computer chassis. Such a path can be provided by disposing the heat-generating components inside of an air duct that has a fluid connection with an inlet to the computer chassis and a fluid connection with an outlet to the computer chassis. The cooling air is guided to flow into the air duct, over and around the heat-generating components installed within the air duct, and out of the computer chassis. While such cooling air can effectively dissipate the heat generated by the component, the structural geometry required to form an air duct within a computer chassis can be difficult due to the limited space and placement of the heat-generating components. For example, effectively positioning the air duct within the computer chassis can require a portion of the air duct to be installed over another component within the computer chassis. Such installation over another component requires the air duct to be removed whenever access is required to the covered component. A need exists for a configurable air duct that can provide access to components beneath it that would otherwise be covered by having a configuration where a portion of the structure is movable to provide access to the covered components.

### SUMMARY OF THE INVENTION

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to certain aspects of the present disclosure, a configurable duct for a computer chassis includes a fixed part and a movable part. The fixed part includes a first base wall, a first side wall, and a second side wall. The first side wall extends along a first edge of the first base wall, and the second side wall extends along a second edge of the first base wall. The first base wall, the first side wall, and the second side wall form a portion of three sides of the configurable duct. The first base wall is configured to attach to the computer chassis. The movable part includes a second base wall and is rotatably attached to the fixed part. The movable part is rotatable between a first configuration and a second configuration. The second base wall is generally parallel to the first base wall and blocks access to a portion of the computer chassis in the first configuration. The movable part is rotated away from the portion of the computer chassis in the second configuration such that the portion of the computer chassis is exposed in the second configuration for providing access to the portion of the computer chassis.

According to certain aspects of the present disclosure, the movable part further comprises a third side wall, a fourth side wall, and an end wall. The third side wall extends along a third edge of the second base wall. The fourth side wall extends along a fourth edge of the second base wall. The end wall is disposed generally orthogonal to the second base wall, the third side wall, and the fourth side wall.

According to certain aspects of the present disclosure, the movable part is rotatably attached to the fixed part by a rotation hinge.

According to certain aspects of the present disclosure, the rotation hinge includes posts extending from either the first and second side walls or the third and fourth side walls. The posts rotate within holes through either the third and fourth side walls or the first and second side walls, respectively.

According to certain aspects of the present disclosure, each of the first and second side walls includes a stop. Each of the third and fourth side walls makes contact with the respective stop on each of the first and second side walls. Each of the first and second side walls further includes a locking dimple extending from a flexible tab. Each of the third and fourth side walls includes a dimple hole. Each locking dimple is accommodated by the respective dimple hole through each of the third and fourth side walls to secure the moving part in the first configuration.

According to certain aspects of the present disclosure, the first base wall attaches to the computer chassis via a two-sized slot disposed through the first base wall. The two-sized slot attaches to a T-shaped pin that extends from the computer chassis.

According to certain aspects of the present disclosure, the first base wall attaches to the computer chassis via a screw that extends through a hole in the first base wall. The screw is threaded into the computer chassis.

According to certain aspects of the present disclosure, the moving part in the first configuration covers access to a riser board that attaches to the portion of the computer chassis.

According to certain aspects of the present disclosure, the moving part in the second configuration is rotated away from the riser board such that the riser board is exposed.

According to certain aspects of the present disclosure, a method of attaching a configurable duct to a computer chassis includes providing the configurable duct with a fixed part rotatably attached with a movable part. The movable part is rotatable between a first configuration and a second configuration. The method further includes attaching the fixed part to the computer chassis with the movable part in the first configuration. The movable part has a base wall that blocks access to a portion of the computer chassis in the first configuration. The method further includes rotating the movable part from the first configuration to the second configuration such that the portion of the computer chassis is exposed. The base wall is rotated away to allow access to the portion of the computer chassis in the second configuration. The method further includes attaching a riser board to the portion of the computer chassis. The method further includes rotating the movable part from the second configuration to the first configuration to prevent access to the riser board.

According to certain aspects of the present disclosure, a computing system includes a computer chassis, a heat-generating electronic component, and a configurable duct. The configurable duct is attached in part to the computer chassis. The configurable duct includes a fixed part and a movable part. The fixed part includes a first base wall, a first side wall, and a second side wall. The first side wall extends along a first edge of the first base wall, and the second side wall extends along a second edge of the first base wall. The first base wall, the first side wall, and the second side wall form a portion of three sides of the configurable duct. The first base wall is attached to the computer chassis. The movable part includes a second base wall. The movable part is rotatably attached to the fixed part, and is rotatable between a first configuration and a second configuration. The second base wall is generally parallel to the first base wall and blocks access to a portion of the computer chassis in the first configuration. The movable part is rotated away from the portion of the computer chassis in the second configuration such that the portion of the computer chassis is exposed

According to certain aspects of the present disclosure, the movable portion further comprises a third side wall, a fourth side wall, and an end wall. The third side wall extends along a third edge of the second base wall. The fourth side wall extends along a fourth edge of the second base wall. The end wall is disposed generally orthogonal to the second base wall, the third side wall, and the fourth side wall.

According to certain aspects of the present disclosure, the movable part is rotatably attached to the fixed part by a rotation hinge.

According to certain aspects of the present disclosure, the rotation hinge includes posts extending from either the first and second side walls or the third and fourth side walls. The posts rotate within holes through either the third and fourth side walls or the first and second side walls, respectively.

According to certain aspects of the present disclosure, each of the first and second side walls includes a stop. Each of the third and fourth side walls makes contact with the respective stop on each of the first and second side walls. Each of the first and second side walls further includes a locking dimple extending from a flexible tab. Each of the third and fourth side walls includes a dimple hole. Each locking dimple is accommodated by the respective dimple hole through each of the third and fourth side walls to secure the moving part in the first configuration.

According to certain aspects of the present disclosure, the first base wall attaches to the computer chassis via a two-sized slot disposed through the first base wall. The two-sized slot attaches to a T-shaped pin that extends from the computer chassis.

According to certain aspects of the present disclosure, the first base wall attaches to the computer chassis via a screw that extends through a hole in the first base wall to thread into the computer chassis.

According to certain aspects of the present disclosure, the moving part in the first configuration covers access to a riser board that attaches to the portion of the computer chassis.

According to certain aspects of the present disclosure, the moving part in the second configuration is rotated away from the riser board such that the riser board is exposed.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1 is a perspective schematic view showing an exemplary air duct in a disassembled state on the left and the exemplary air duct in an assembled state on the right, according to certain aspects of the present disclosure.

FIG. 2 is a perspective schematic view showing an exemplary moving part of an exemplary air duct in a first configuration on the left and in a second configuration on the right, according to certain aspects of the present disclosure.

FIG. 3 is a perspective schematic view of an exemplary air duct being lowered into position for placement on a computer chassis on the left and being secured to the computer chassis on the right, according to certain aspects of the present disclosure.

FIG. 4 is a perspective schematic view of an exemplary air duct attached to a computer chassis in a second configuration and without a riser board, according to certain aspects of the present disclosure.

FIG. 5 is a perspective schematic view of a riser board being installed on a computer chassis with an exemplary air duct already attached to the computer chassis and in the second configuration, according to certain aspects of the present disclosure.

FIG. 6 is a perspective schematic view of a riser board after being installed on a computer chassis with an exemplary air duct already attached to the computer chassis and in the second configuration, according to certain aspects of the present disclosure.

FIG. 7 is a perspective schematic view of an exemplary air duct attached to a computer chassis in the first configuration with a riser board, according to certain aspects of the present disclosure.

FIG. 8 is a perspective schematic view of an exemplary air duct attached to a computer chassis in the second configuration with a riser board, according to certain aspects of the present disclosure.

FIG. 9 is a schematic perspective view of a peripheral card mounted in an exemplary air duct with heat-generating components mounted on a side of the peripheral card facing into the air duct, according to certain aspects of the present disclosure.

FIG. 10 is a flow diagram for the steps of a method of attaching a configurable duct to a computer chassis, according to certain aspects of the present disclosure.

### DETAILED DESCRIPTION

The current invention is a configurable air duct for a computer chassis. The configurable duct is configurable between a first configuration and a second configuration. In the first configuration, a portion of the configurable duct covers and blocks access to a portion of the computer chassis. In the second configuration, the part of the configurable duct that covers the portion of the computer chassis is rotated such that the portion of the computer chassis is exposed.

Various embodiments are described with reference to the attached figures, where like reference numerals are used throughout the figures to designate similar or equivalent elements. Each reference numeral identifies the figure in which the reference numeral first appears based on the first digit (for three-digit reference numerals) or the first two digits (for four-digit reference numerals) corresponding to the figure numeral of the figure. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

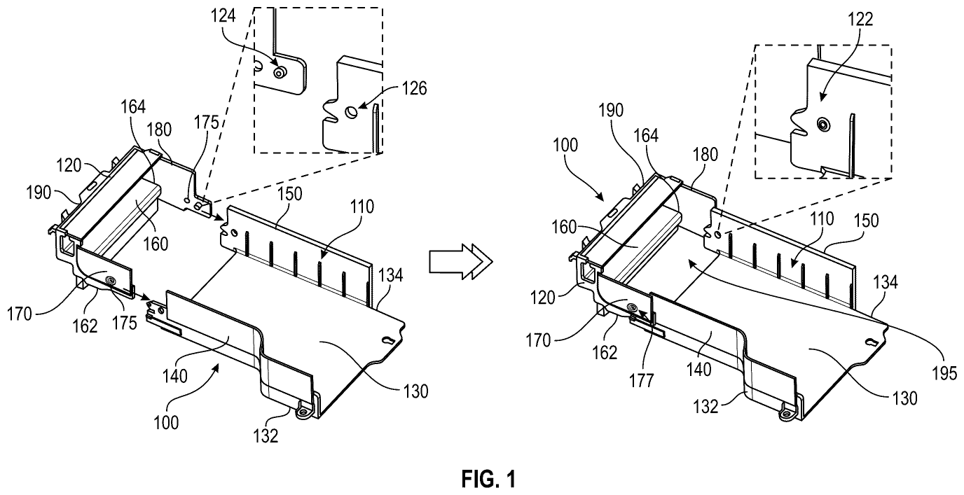

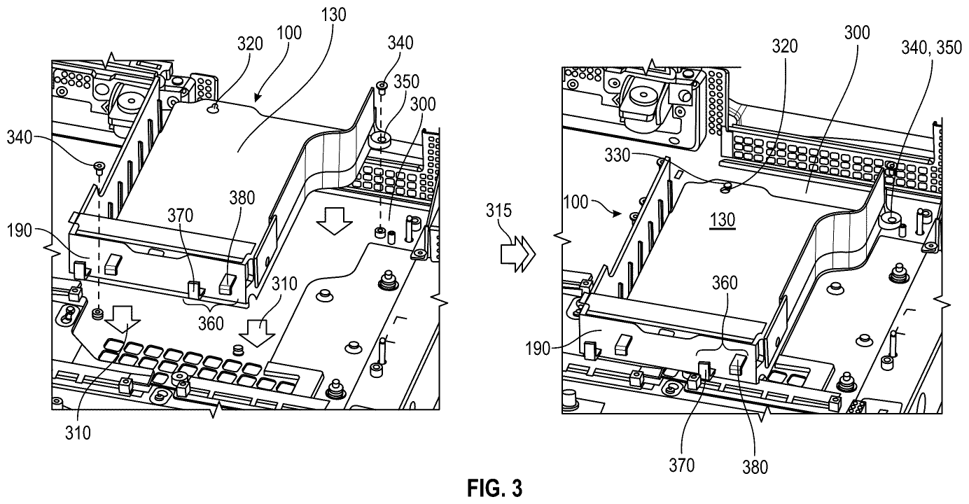

Referring to FIG. 1, in an embodiment, an air duct 100 is shown in a disassembled state on the left side and an assembled state on the right side. The air duct 100 includes a fixed part 110 and a movable part 120. The fixed part 110 includes a first base wall 130, a first side wall 140, and a second side wall 150. The first side wall 140 extends along a first edge 132 of the first base wall 130. The second side wall 150 extends along a second edge 134 of the first base wall 130. The first base wall 130, the first side wall 140, and the second side wall 150 form a portion of three sides of the air duct 100. The air duct 100 ultimately attaches to a computer chassis 300 (see FIG. 3) that is a base for a plurality of layers or trays that are stacked on top of one another to form a server. A fourth side or cover for the air duct 100 is provided by a tray (not shown) that is positioned over the layer including the air duct 100. Therefore, only three sides of the air duct 100 are needed.

The movable part 120 includes a second base wall 160. The movable part 120 includes a third side wall 170 extending along a third edge 162 of the second base wall 160. The movable part 120 further includes a fourth side wall 180 extending along a fourth edge 164 of the second base wall 160. The movable part 120 further includes an end wall 190 disposed generally orthogonal to the second base wall 160, the third side wall 170, and the fourth side wall 180.

The movable part 120 is rotatably attached to the fixed part 110 by a rotation hinge 122. The rotation hinge 122 includes a post 124 extending from each of the third and fourth side walls 170, 180. Each post 124 is configured to rotate within a hole 126 disposed through each of the first and second side walls 140, 150. Alternatively, the rotation hinge 122 includes a post 124 extending from each of first and second side walls 140, 150. Each post 124 is configured to rotate within a hole 126 disposed through each of the third and fourth side walls 170, 180.

Stil referring to FIG. 1, when the moving part 120 is in the first configuration as shown on the right, there remains a space 195 between the first base wall 130 and the second base wall 160. As will be further described below, this space 195 aligns with openings in the computer chassis 300 (see FIG. 3) to allow cooling air to flow into or out of the air duct 100. Each of the third and fourth side walls 170, 180 includes a dimple hole 175. Each dimple hole 175 is part of a dimple lock 177 that is further described below.

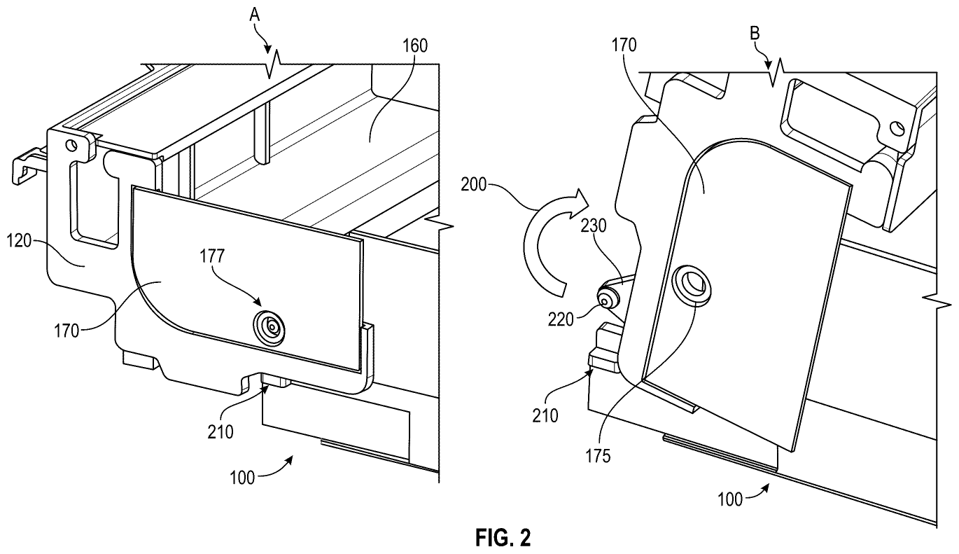

Referring to FIG. 2, the movable part 120 is shown rotatably attached to the fixed part 110. The movable part 120 is rotatable between a first configuration A shown on the left and a second configuration B shown on the right. In the first configuration A, the second base wall 160 is generally parallel to the first base wall 130. As is shown and described more fully in regard to FIG. 3 below, in the first configuration A, the second base wall 160 blocks access to a portion of the computer chassis 300 in which the air duct 100 is mounted. In the second configuration B, the movable part 120 is rotated away from the first configuration as shown by the curved arrow 200 such that the portion of the chassis blocked by second base wall 160 is exposed.

Each of the first and second side walls 140, 150 includes a stop 210 and a locking dimple 220 extending from a flexible tab 230. Each of the third and fourth side walls 170, 180 includes the dimple hole 175. When the movable part 120 is moved from the second configuration B toward the first configuration A, each of the third and fourth walls 170, 180 contacts the stop 210 on each of the first and second side walls 140, 150. The stop 210 prevents the movable part 120 from further rotating past the first configuration A. Further, the locking dimples 220 snap into the dimple holes 175 to produce the dimple lock 177 that secures the moving part 120 in the first configuration A.

Referring to FIG. 3, an air duct 100 is shown on the left being lowered towards a computer chassis 300 as indicated by the block arrows 310. The double arrows 315 indicate a progression of placement for the air duct 100 into the computer chassis 300. As shown on the right, the first base wall 130 attaches to the computer chassis 300 via at least one two-sized slot 320 disposed through the first base wall 130. The two-sized slot 320 attaches to a T-shaped pin 330 that extends from the computer chassis 300. Alternatively, or in addition to the connection between the two-sized slot 320 and T-shaped pin 330, the first base wall 130 attaches to the computer chassis 300 via at least one screw 340 that extends through a hole 350 in the first base wall 130 to thread into the computer chassis 300. The end wall 190 of the moving part 120 includes one or more sets of cable guiding brackets 360. Each set of cable guiding brackets 360 has an upwardly hooked bracket 370 and a downwardly hooked bracket 380.

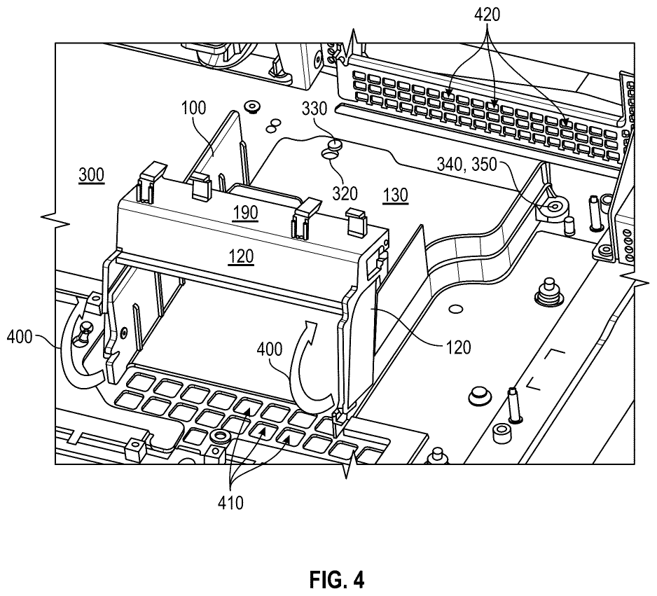

Referring to FIG. 4, the air duct 100 is illustrated attached to the computer chassis 300 with the movable part 120 rotated up into the second configuration B, as indicated by the curved arrows 400. The computer chassis 300 includes openings 410 disposed under the air duct 100 such that the openings 410 align with the space 195 shown in FIG. 1. This alignment of the openings 410 and the space 195 allows cooling air to enter or exit the air duct 100.

The computer chassis 300 further includes openings 420 in fluid communication with an end of the air duct 100 opposite to the end wall 190. The openings 420 provide a path for cooling air that has entered the air duct through the openings 410 and the space 195 to exit the computer chassis 300. Alternatively, the openings 420 provide an inlet path into the computer chassis 300 for cooling air to enter the air duct 100 and ultimately exit the computer chassis 300 through the space 195 and the openings 410.

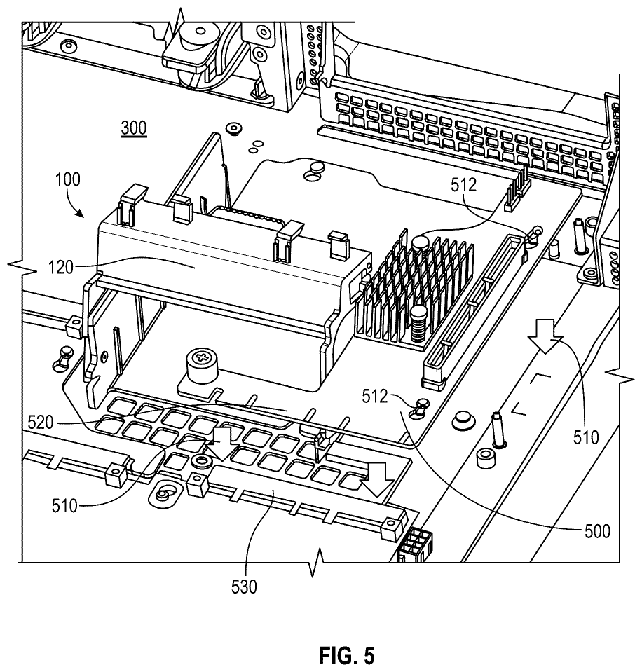

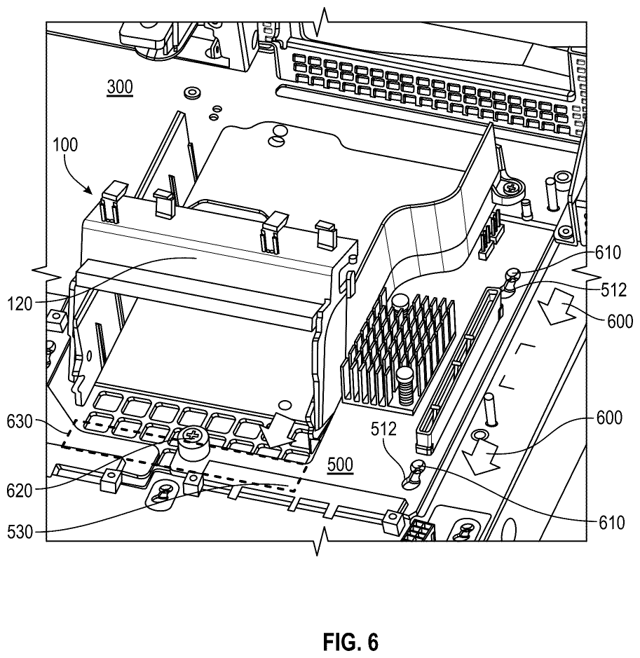

Referring to FIG. 5, a riser board 500 is shown being lowered toward the computer chassis 300 as indicated by the block arrows 510. The riser board includes two-sized slots 512 that are lined up with T-shaped pins not visible in FIG. 5 (see FIG. 6) extending from the computer chassis 300. The riser board 500 also includes an edge connector 520 that mates with a connector slot 530 mounted on the computer chassis 300.

FIG. 6 shows the riser board 500 connected to the computer chassis 300 after the edge connector 520 has been mated with the connector slot 530, as indicated by the block arrows 600. The tops of the T-shaped pins 610 can be seen in the two-sized slots 512 securing the air duct 100 to the computer chassis 300. The riser board 500 is further attached to the chassis by a screw 620. The moving part 120 is in the second configuration B during the installation of the riser board 500, as shown in FIGS. 5 and 6. A portion 630 of the computer chassis 300 (and the riser board 500) that is covered by the moving part 120 in the first configuration A is schematically outlined in FIG. 6 by the dashed area labeled as the portion 630.

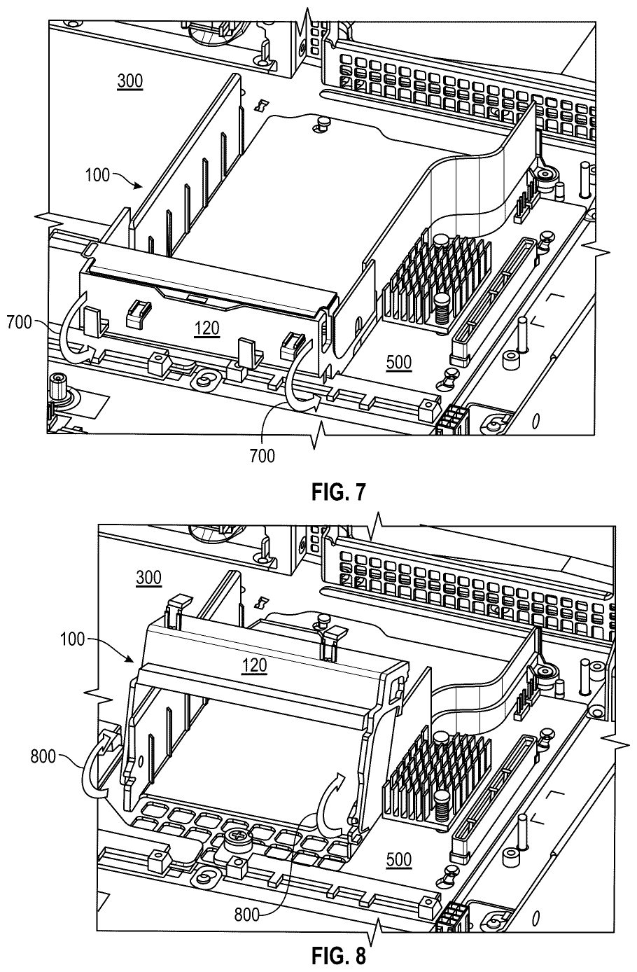

Referring to FIG. 7, the air duct 100 is in the first configuration A. The moving part 120 has been rotated as indicated by the arrows 700 from the second configuration B, as shown in FIG. 6 to the first configuration A. In this configuration, the moving part 120 covers the portion 630 of the computer chassis 300 that was schematically outlined in FIG. 6. The moving part 120 in the first configuration A also covers a portion of the riser board 500 that is attached to the computer chassis 300. The moving part 120 blocks access to the covered portion 630 of the computer chassis 300, to the covered portion of the riser board 500, and to the screw 620 that assists in securing the riser board 500 to the computer chassis 300.

Referring to FIG. 8, when access to the riser board 500 is needed, the moving part 120 is rotated away from the riser board 500, as shown by the curved arrows 800, such that the riser board 500 is exposed. The configurable structure of the air duct 100 eliminates the need to remove and possibly disassemble the air duct 100 when access is required to the riser board 500 in a computer chassis 300 having limited space. Eliminating the steps of removal and possible disassembly of the air duct 100 also eliminates any need for possible reassembly and reinstallion the air duct 100. Moreover, the rotating structure of the air duct 100 can also save space, so that an overall length of the computer chassis 300 does not need to be extended, thereby saving costs.

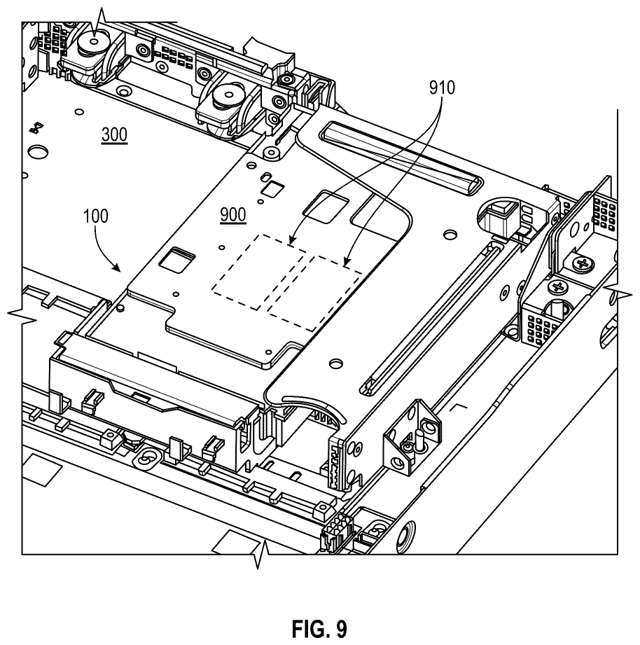

Referring to FIG. 9, in an embodiment, a printed circuit board such as a peripheral card 900 is mounted within the air duct 100. The peripheral card 900 has heat-generating components 910 (not visible in FIG. 9) mounted on a side of the peripheral card 900 facing into the air duct 100. Although the heat-generating components 910 are not visible in FIG. 9, their exemplary positions on the peripheral card 900 are schematically shown by the dashed rectangles marked as 910. Cooling air that is directed through the air duct 100 dissipates heat from the heat-generating components 910 and carries the heat out of the computer chassis 300 via the air duct 100.

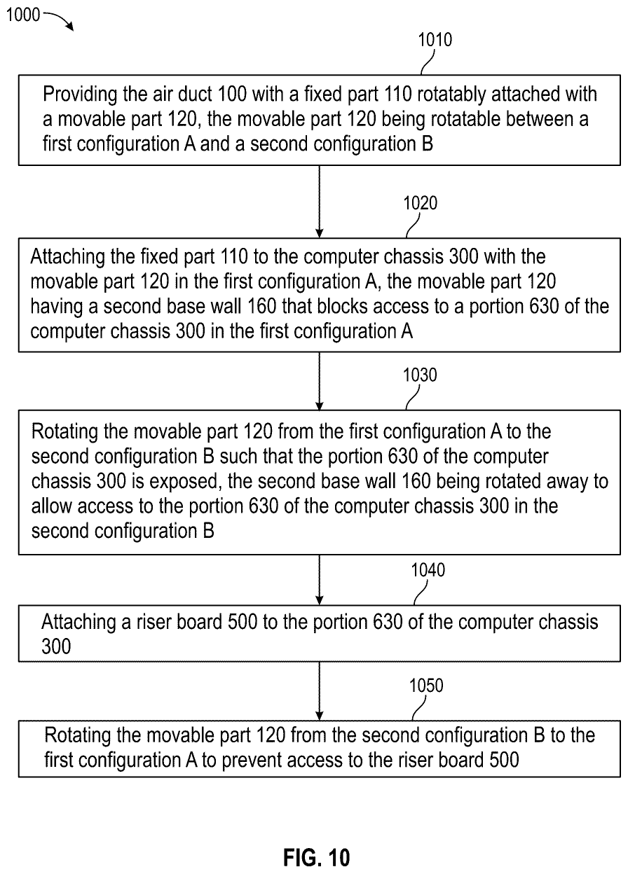

Referring to FIG. 10, a method 1000 of attaching the air duct 100 to the computer chassis 300 starts at step 1010 by providing the configurable duct (air duct 100) with the fixed part 110 rotatably attached with the movable part 120. The movable part 120 is configurable between the first configuration A and the second configuration B. At step 1020, the method 1000 continues by attaching the fixed part 110 to the computer chassis 300 with the movable part 120 in the first configuration A. The movable part 120 has the second base wall 160 that blocks access to the portion 630 of the computer chassis 300 in the first configuration A. At step 1030, the method 100 continues by rotating the movable part 120 from the first configuration A to the second configuration B such that the portion 630 of the computer chassis 300 is exposed. The second base wall 160 is rotated away to allow access to the portion 630 of the computer chassis 300 in the second configuration B. Alternatively, at step 1020, the fixed part 110 can be attached to the computer chassis 300 with the movable part 120 in the second configuration B such that step 1030 can be skipped. At step 1040, the method 1000 continues by attaching a computer component, for example, the riser board 500, to the portion 630 of the computer chassis 300. The method 1000 continues at step 1050 by rotating the movable part 120 from the second configuration B to the first configuration A to cover and thereby prevent access to the riser board 500.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. A configurable duct for a computer chassis, the configurable duct comprising:
a fixed part including a first base wall, a first side wall, and a second side wall, the first side wall extending along a first edge of the first base wall, the second side wall extending along a second edge of the first base wall, the first base wall, the first side wall, and the second side wall forming a portion of three sides of the configurable duct, the first base wall configured to attach to the computer chassis; and
a movable part including a second base wall, the movable part being rotatably attached to the fixed part, the movable part being rotatable between a first configuration and a second configuration, the second base wall being generally parallel to the first base wall and blocking access to a portion of the computer chassis in the first configuration; the movable part being rotated away from the portion of the computer chassis in the second configuration, the portion of the computer chassis being exposed in the second configuration for providing access to the portion of the computer chassis.

2. The configurable duct of claim 1, wherein the movable part further comprises a third side wall extending along a third edge of the second base wall, a fourth side wall extending along a fourth edge of the second base wall, and an end wall disposed generally orthogonal to the second base wall, the third side wall, and the fourth side wall.

3. The configurable duct of claim 2, wherein the movable part is rotatably attached to the fixed part by a rotation hinge.

4. The configurable duct of claim 3, wherein the rotation hinge includes posts extending from either the first and second side walls or the third and fourth side walls, the posts disposed to rotate within holes disposed through either the third and fourth side walls or the first and second side walls, respectively.

5. The configurable duct of claim 4, wherein each of the first and second side walls includes a stop and a locking dimple extending from a flexible tab, and each of the third and fourth side walls includes a dimple hole, each of the third and fourth side walls making contact with a respective stop on each of the first and second side walls, each locking dimple being accommodated by a respective dimple hole through each of the third and fourth side walls to secure the moving part in the first configuration.

6. The configurable duct of claim 1, wherein the first base wall attaches to the computer chassis via a two-sized slot disposed through the first base wall, the two-sized slot attaching to a T-shaped pin that extends from the computer chassis.

7. The configurable duct of claim 1, wherein the first base wall attaches to the computer chassis via a screw that extends through a hole in the first base wall, the screw being threaded into the computer chassis.

8. The configurable duct of claim 1, wherein the moving part in the first configuration covers access to a riser board that attaches to the portion of the computer chassis.

9. The configurable duct of claim 8, wherein the moving part in the second configuration is rotated away from the riser board such that the riser board is exposed.

10. A method of attaching a configurable duct to a computer chassis, the method comprising:
providing the configurable duct with a fixed part rotatably attached with a movable part, the movable part being rotatable between a first configuration and a second configuration;
attaching the fixed part to the computer chassis with the movable part in the first configuration, the movable part having a base wall that blocks access to a portion of the computer chassis in the first configuration;
rotating the movable part from the first configuration to the second configuration such that the portion of the computer chassis is exposed, the base wall being rotated away to allow access to the portion of the computer chassis in the second configuration;
attaching a riser board to the portion of the computer chassis; and
rotating the movable part from the second configuration to the first configuration to prevent access to the riser board.

11. A computing system, comprising:
a computer chassis;
a heat-generating electronic component; and
a configurable duct attached in part to the computer chassis, the configurable duct including:
a fixed part including a first base wall, a first side wall, and a second side wall, the first side wall extending along a first edge of the first base wall, the second side wall extending along a second edge of the first base wall, the first base wall, the first side wall, and the second side wall forming a portion of three sides of the configurable duct, the first base wall being attached to the computer chassis; and
a movable part including a second base wall, the movable part rotatably attached to the fixed part, the movable part being rotatable between a first configuration and a second configuration, the second base wall being generally parallel to the first base wall and blocking access to a portion of the computer chassis in the first configuration, the movable part being rotated away from the portion of the computer chassis in the second configuration such that the portion of the computer chassis is exposed.

12. The computing system of claim 11, wherein the movable portion further comprises a third side wall extending along a third edge of the second base wall, a fourth side wall extending along a fourth edge of the second base wall, and an end wall disposed generally orthogonal to the second base wall, the third side wall, and the fourth side wall.

13. The computing system of claim 12, wherein the movable part is rotatably attached to the fixed part by a rotation hinge.

14. The computing system of claim 13, wherein the rotation hinge includes posts extending from either the first and second side walls or the third and fourth side walls, the posts disposed to rotate within holes disposed through either the third and fourth side walls or the first and second side walls, respectively.

15. The computing system of claim 14, wherein each of the first and second side walls includes a stop and a locking dimple extending from a flexible tab, and each of the third and fourth side walls includes a dimple hole, each of the third and fourth side walls making contact with a respective stop on each of the first and second side walls, each locking dimple being accommodated by a respective dimple hole through each of the third and fourth side walls to secure the moving part in the first configuration.

16. The computing system of claim 11, wherein the first base wall attaches to the computer chassis via a two-sized slot disposed through the first base wall, the two-sized slot attaching to a T-shaped pin that extends from the computer chassis.

17. The computing system of claim 11, wherein the first base wall attaches to the computer chassis via a screw that extends through a hole in the first base wall to thread into the computer chassis.

18. The computing system of claim 11, wherein the moving part in the first configuration covers access to a riser board that attaches to the portion of the computer chassis.

19. The computing system of claim 18, wherein the moving part in the second configuration is rotated away from the riser board such that the riser board is exposed.
